(19) United States
(12) Patent Application Publication
(10) Pub. No.: US 2008/0073107 A1
(43) Pub. Date: Mar. 27, 2008

(54) Printed Circuit Board

(75) Inventor: Mitsuru HONJO, Osaka (JP)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: NITTO DENKO CORPORATION, Osaka (JP)

(21) Appl. No.: 11/854,012

(22) Filed: Sep. 12, 2007

(30) Foreign Application Priority Data
Sep. 26, 2006 (JP) 2006-260086

(51) Int. Cl. H05K 1/00

(52) U.S. Cl. 174/250; 174/258

(57) ABSTRACT

A first wiring pattern and a second ground layer are formed on one surface of a base insulating layer, and a second wiring pattern and a first ground layer are formed on the other surface of the base insulating layer. A metal plating layer connecting the first and second wiring patterns to each other is formed in a through hole of the base insulating layer. A cover insulating layer is formed on the other surface of the base insulating layer so as to cover the first ground layer and the second wiring pattern and has a through hole on an area opposite to a part of the first wiring pattern. A high dielectric insulator is formed in the through hole of the cover insulating layer.

### BACKGROUND OF THE INVENTION

1. Field of the Invention

The present invention relates to a printed circuit board used for various types of electric equipment or electronic equipment.

2. Description of the Background Art

Conventionally, printed circuit boards have been used for various types of electric equipment or electronic equipment. In order to make the electric equipment and the electronic equipment smaller in size and lightweight, wiring patterns on the printed circuit boards are made higher in density, and electronic components are mounted on the miniaturized printed circuit boards.

In recent years, in order to make the printed circuit boards even higher in density and smaller in size, a printed circuit board having a multilayer structure has been developed (see JP 2000-323847 A, for example).

The conventional printed circuit board has the following problems. FIG. 3 is a schematic sectional view simply showing the configuration of the conventional printed circuit board.

As shown in FIG. 3, a base insulating layer 1 has a first surface and a second surface. Prescribed wiring patterns 2a and 2b are respectively formed on one surface and the other surface of the base insulating layer 1.

A metal plating layer 3 for electrically connecting the wiring pattern 2a and the wiring pattern 2b to each other is formed in a through hole (not shown) provided within the base insulating layer 1.

A first ground layer 4a is formed in an area, which is opposite to the wiring pattern 2a formed on the one surface of the base insulating layer 1, on the other surface thereof. A second ground layer 4b is formed in an area, which is opposite to the wiring pattern 2b formed on the other surface of the base insulating layer 1, on the one surface thereof.

No ground layers are respectively formed in an area A in the vicinity of the metal plating layer 3 on the other surface of the base insulating layer 1, which is opposite to the wiring pattern 2a formed on the one surface of the base insulating layer 1, and an area B in the vicinity of the metal plating layer 3 on the one surface of the base insulating layer 1, which is opposite to the wiring pattern 2b formed on the other surface of the base insulating layer 1. This can prevent the printed circuit board from being short-circuited.

Since no ground layers are respectively formed in the areas A and B opposite to the wiring patterns 2a and 2b, however, characteristic impedances in the areas A and B respectively differ from characteristic impedances in the other areas in transmission path composed of the wiring patterns 2a and 2b and the ground layers 4a and 4b. Therefore, the characteristic impedance in the transmission path become discontinuous. This results in loss in the transmission path in the printed circuit board. Consequently, the transmission efficiency of a signal is reduced.

### SUMMARY OF THE INVENTION

An object of the present invention is to provide a printed circuit board capable of inhibiting characteristic impedances in a transmission path from being discontinuous.

(1) A printed circuit board according to an aspect of the present invention comprises a base insulating layer having a first surface and a second surface, a first ground layer formed on the first surface of the base insulating layer, a first conductor pattern formed on the second surface of the base insulating layer such that the first conductor pattern is opposite to the first ground layer excluding a part of the first conductor pattern, and a first high dielectric insulator having a dielectric constant higher than that of the base insulating layer on a first area, which is opposite to the part of the first conductor pattern, on the first surface of the base insulating layer.

In the printed circuit board, the first ground layer is formed on the first surface of the base insulating layer. The first conductor pattern is formed on the second surface of the base insulating layer such that the first conductor pattern, excluding its part, is opposite to the first ground layer. The first high dielectric insulator having a dielectric constant higher than that of the base insulating layer is formed on the first area, which is opposite to the part of the first conductor pattern, on the first surface of the base insulating layer. In this case, the first conductor pattern and the first ground layer constitute a transmission path.

Such a configuration causes a characteristic impedance in the first area in the transmission path to be approximately equal to a characteristic impedance in the other area. This allows the characteristic impedance in the transmission path in the printed circuit board to be made uniform. That is, it is possible to inhibit the characteristic impedance in the transmission path from being discontinuous in the printed circuit board. Consequently, the transmission efficiency of a signal (a high-frequency signal) is inhibited from being reduced in the printed circuit board.

(2) The printed circuit board may further include a first cover insulating layer formed on the first surface of the base insulating layer so as to cover the first ground layer and having a first hole on the first area, wherein the first hole may be filled with the first high dielectric insulator, and the dielectric constant of the first high dielectric insulator may be higher than that of the first cover insulating layer.

In this case, the first cover insulating layer having the first hole on the first area is formed on the first surface of the base insulating layer so as to cover the first ground layer. Further, the first hole is filled with the first high dielectric insulator having a dielectric constant higher than that of the first cover insulating layer. Such a configuration allows the first high dielectric insulator to be easily formed on the first area.

(3) The first high dielectric insulator may include resin and a high dielectric substance. In this case, the insulator having a high dielectric constant can be produced easily.

(4) The first high dielectric insulator may be formed by dispersing the high dielectric substance in the resin.

In this case, the dielectric constant of the first high dielectric insulator can be controlled depending on the amount of the high dielectric substance dispersed in the resin.

(5) The high dielectric substance may include barium titanate. In this case, the cost of the high dielectric substance can be reduced by using barium titanate.

(6) The dielectric constant of the first high dielectric insulator may be not less than 10 nor more than 40. In this case, the characteristic impedance in the first area in the transmission path becomes approximately equal to the characteristic impedance in the other area. This allows the characteristic impedance in the transmission path in the printed circuit board to be made uniform. Consequently, it is possible to sufficiently inhibit the characteristic impedance in the transmission path from being discontinuous in the printed circuit board.

(7) The printed circuit board may further include a second ground layer formed in an area different from the first conductor pattern on the second surface of the base insulating layer, a second conductor pattern formed on the first surface of the base insulating layer such that the second conductor pattern is opposite to the second ground layer excluding a part of the second conductor pattern, and a second high dielectric insulator having a dielectric constant higher than that of the base insulating layer on a second area, which is opposite to the part of the second conductor pattern, on the second surface of the base insulating layer.

In this case, the second ground layer is formed in the area different from the first conductor pattern on the second surface of the base insulating layer. The second conductor pattern is formed on the first surface of the base insulating layer such that the second conductor pattern, excluding its part, is opposite to the second ground layer. The second high dielectric insulator having a dielectric constant higher than that of the base insulating layer is formed on the second area, which is opposite to the part of the second conductor pattern, on the second surface of the base insulating layer. In this case, the second conductor pattern and the second ground layer constitute a transmission path.

Such a configuration causes a characteristic impedance in the second area in the transmission path to be approximately equal to a characteristic impedance in the other area. This allows the characteristic impedance in the transmission path in the printed circuit board to be made uniform. That is, it is possible to inhibit the characteristic impedance in the transmission path from being discontinuous in the printed circuit board. Consequently, the transmission efficiency of a signal (a high-frequency signal) is inhibited from being reduced in the printed circuit board.

(8) The printed circuit board may further include a second cover insulating layer formed on the second surface of the base insulating layer so as to cover the second ground layer and having a second hole on the second area, wherein the second hole may be filled with the second high dielectric insulator.

In this case, the second cover insulating layer having the second hole on the second area is formed on the second surface of the base insulating layer so as to cover the second ground layer. Further, the second hole is filled with the second high dielectric insulator having a dielectric constant higher than that of the second cover insulating layer. Such a configuration allows the second high dielectric insulator to be easily formed on the second area.

(9) The printed circuit board may further include a connecting conductor provided within the base insulating layer for connecting an end of the first conductor pattern and an end of the second conductor pattern. One end of the first ground layer may be spaced apart from the conductor, wherein one end of the second ground layer may be spaced apart from the connecting conductor, the first high dielectric insulator may be provided between the one end of the first ground layer and the connecting conductor, and the second high dielectric insulator may be provided between the one end of the second ground layer and the connecting conductor.

In this case, the connecting conductor provided within the base insulating layer connects the end of the first conductor pattern and the end of the second conductor pattern. Consequently, a transmission path composed of the first conductor pattern and the first ground layer and a transmission path composed of the second conductor pattern and the second ground layer are electrically connected to each other. The one end of the first ground layer is spaced apart from the connecting conductor, and the one end of the second ground layer is spaced apart from the connecting conductor.

In such a configuration, the first high dielectric insulator is provided between the one end of the first ground layer and the connecting conductor, and the second high dielectric insulator is provided between the one end of the second ground layer and the connecting conductor. Therefore, the characteristic impedances in the first and second areas in the transmission paths respectively become approximately equal to the characteristic impedances in the other areas. This allows the characteristic impedance in the transmission path in the printed circuit board to be made uniform. That is, it is possible to inhibit the characteristic impedance in the transmission path from being discontinuous in the printed circuit board. Consequently, the transmission efficiency of a signal (a high-frequency signal) is inhibited from being reduced in the printed circuit board.

Other features, elements, characteristics, and advantages of the present invention will become more apparent from the following description of preferred embodiments of the present invention with reference to the attached drawings.

### BRIEF DESCRIPTION OF THE DRAWINGS

FIG. 1 is schematic sectional views showing an example of a method of manufacturing a printed circuit board according to an embodiment;

FIG. 2 is a top view, a cross-sectional view, and a bottom view of the printed circuit board according to the embodiment; and

FIG. 3 is a schematic sectional view simply showing the configuration of a conventional printed circuit board.

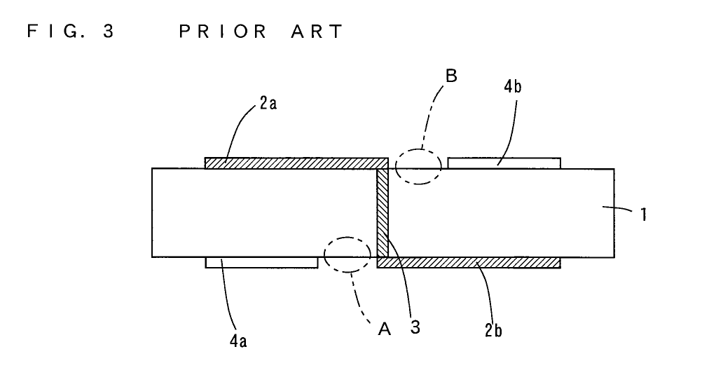

### DESCRIPTION OF THE PREFERRED EMBODIMENTS

A printed circuit board according to an embodiment of the present invention will be now described while referring to the drawings. The printed circuit board according to the present embodiment is a flexible printed circuit board.

### (1) Method of Manufacturing Printed Circuit Board

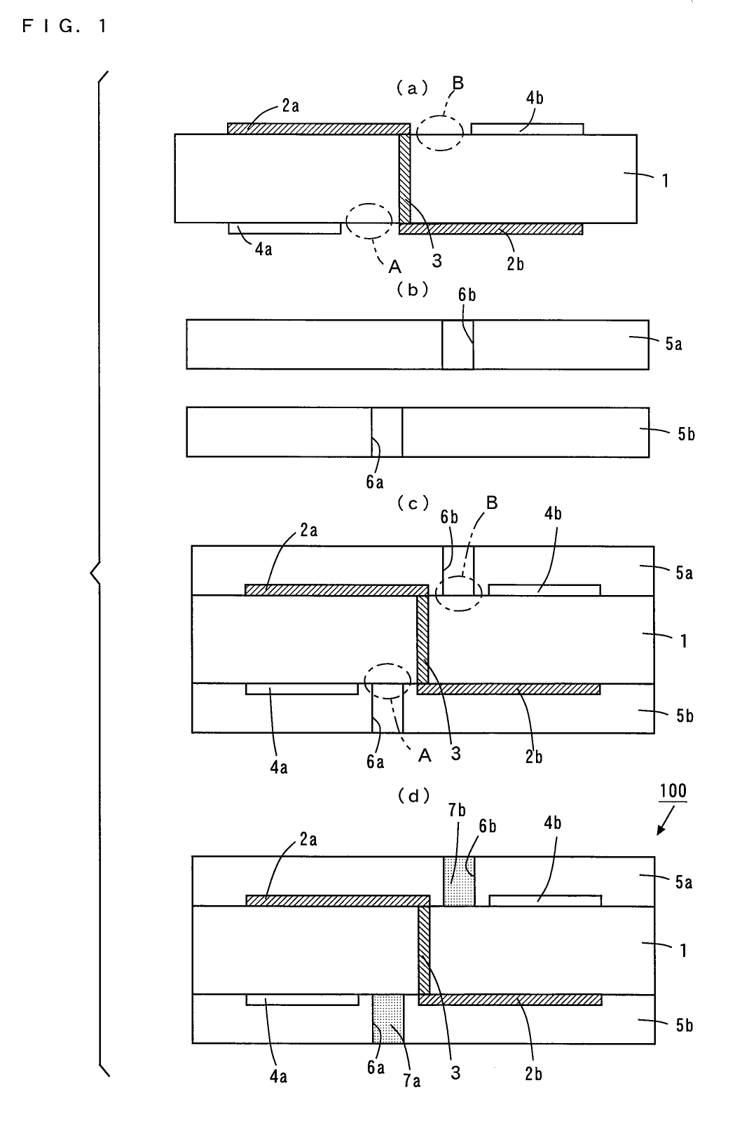

FIG. 1 is schematic sectional views showing an example of a method of manufacturing a printed circuit board according to the present embodiment.

As shown in FIG. 1 (a), prescribed wiring patterns 2a and 2b composed of copper, for example, are respectively formed on one surface and the other surface of a base insulating layer 1 composed of a polyimide film, for example. Note that a base insulating layer 1 composed of epoxy resin, acrylic resin, or butyral resin may be used. Further, the dielectric constant of the base insulating layer 1 is approximately 3.2 to 4.0, for example.

A metal plating layer 3 for electrically connecting the wiring pattern 2a and the wiring pattern 2b is formed in a through hole (not shown) provided within the base insulating layer 1. The metal plating layer 3 is a copper plating layer, for example.

A first ground layer 4a composed of copper, for example, is formed in an area, which is opposite to the wiring pattern 2a formed on the one surface of the base insulating layer 1, on the other surface thereof. A second ground layer 4b composed of copper, for example, is formed in an area, which is opposite to the wiring pattern 2b formed on the other surface of the base insulating layer 1, on the one surface thereof. The wiring patterns 2a and 2b and the first and second ground layers 4a and 4b are formed by a known method such as a semi-additive method or a subtractive method.

Here, no ground layers are respectively formed in an area A in the vicinity of the metal plating layer 3 on the other surface of the base insulating layer 1, which is opposite to the wiring pattern 2a formed on the one surface of the base insulating layer 1, and an area B in the vicinity of the metal plating layer 3 on the one surface of the base insulating layer 1, which is opposite to the wiring pattern 2b formed on the other surface of the base insulating layer 1. This can prevent a completed printed circuit board 100, described later, from being short-circuited.

As shown in FIG. 1 (b), cover insulating layers 5a and 5b composed of resin including epoxy, for example, are then prepared. The dielectric constant of the cover insulating layers 5a and 5b is approximately 3.2 to 4.0, for example.

A through hole 6b is formed at a position of the cover insulating layer 5a, which corresponds to the area B in a case where the cover insulating layer 5a is formed on the one surface of the base insulating layer 1. Further, a through hole 6a is formed at a position of the cover insulating layer 5b, which corresponds to the area A in a case where the cover insulating layer 5b is formed on the other surface of the base insulating layer 1.

As shown in FIG. 1 (c), the cover insulating layer 5a is then formed on the one surface of the base insulating layer 1 so as to cover the wiring pattern 2a and the second ground layer 4b. Further, the cover insulating layer 5b is formed on the other surface of the base insulating layer 1 so as to cover the wiring pattern 2b and the first ground layer 4a.

As shown in FIG. 1 (d), the through hole 6b provided in the cover insulating layer 5a is then filled with a high dielectric material having a dielectric constant of 10 to 40, for example, to form a high dielectric insulator 7b.

Furthermore, the through hole 6a provided in the cover insulating layer 5b is filled with a high dielectric material having a dielectric constant of 10 to 40, for example, to form a high dielectric insulator 7a. This causes the printed circuit board 100 according to the present embodiment to be completed.

In the printed circuit board 100, the wiring pattern 2a and the first ground layer 4a constitute a transmission path composed of a microstrip line, and the wiring pattern 2b and the second ground layer 4b constitute a transmission path composed of a microstrip line.

Here, the high dielectric material is obtained by dispersing a high dielectric substance such as barium titanate in resin composed of polyimide or epoxy, for example. The dielectric constant of the high dielectric insulators 7a and 7b is set to a value higher than the dielectric constant of the base insulating layer 1 and the dielectric constant of the cover insulating layers 5a and 5b. The dielectric constant of the high dielectric insulators 7a and 7b can be controlled depending on the amount of the high dielectric substance dispersed in the resin.

The respective thicknesses of the cover insulating layers 5a and 5b are preferably 3 to 100 μm, more preferably 5 to 60 μm, and still more preferably 10 to 30 μm.

The thicknesses of the high dielectric insulators 7a and 7b respectively depend on the thicknesses of the cover insulating layers 5a and 5b, and are preferably 3 to 100 μm, more preferably 5 to 60 μm, and still more preferably 10 to 30 μm.

Used as a method of forming the high dielectric insulators 7a and 7b is a screen printing method, an exposure/development process method, or a coating formation method using a dispenser.

Used as a method of forming the through holes 6a and 6b is a metal mold process method, an exposure/development process method, or a laser process method. The depths of the through holes 6a and 6b respectively depend on the thicknesses of the cover insulating layers 5a and 5b, and are preferably 3 to 100 μm, more preferably 5 to 60 μm, and still more preferably 10 to 30 μm. The respective depths of the through holes 6a and 6b are 5 to 50 μm, for example. The sizes of the through holes 6a and 6b respectively depend on the sizes of the areas A and B.

### (2) Effect of the Present Embodiment

Thus, in the present embodiment, the high dielectric insulator 7a is formed within the cover insulating layer 5b on the area A in the vicinity of the metal plating layer 3 on the other surface of the base insulating layer 1 which is opposite to the wiring pattern 2a formed on the one surface of the base insulating layer 1, and the high dielectric insulator 7b is formed within the cover insulating layer 5a on the area B in the vicinity of the metal plating layer 3 on the one surface of the base insulating layer 1 which is opposite to the wiring pattern 2b formed on the other surface of the base insulating layer 1. Therefore, characteristic impedances in the areas A and B respectively become approximately equal to characteristic impedances in the other areas in the transmission path. This allows the characteristic impedance in the transmission path in the printed circuit board 100 to be made uniform. That is, it is possible to inhibit the characteristic impedance in the transmission path from being discontinuous in the printed circuit board 100. Consequently, the transmission efficiency of a signal (a high-frequency signal) is inhibited from being reduced in the printed circuit board 100.

### (3) Another Embodiment

Although in the above-mentioned embodiment, the wiring patterns 2a and 2b and the ground layers 4a and 4b are respectively provided on both the surfaces of the base insulating layer 1 in the printed circuit board 100, the present invention is not limited to the same. For example, a wiring pattern and a ground layer may be respectively provided on only one surface and the other surface of the base insulating layer 1 or only the other surface and the one surface thereof. In this case, a high dielectric insulator is provided in a cover insulating layer on an area where no ground layer exists on a surface of the base insulating layer 1, which is opposite to the wiring pattern.

A material for the base insulating layer 1 is not limited to that in the above-mentioned example. For example, another insulating material such as polyethylene terephthalate, polyether nitrile, or polyether sulphone may be used.

A material for the wiring patterns 2a and 2b is not limited to copper. For example, another metal material such as a copper alloy, gold, or aluminum may be used.

The metal plating layer 3 is not limited to a copper plating layer. For example, it may be another metal plating layer such as a tin plating layer, a nickel plating layer, or a gold plating layer.

A material for the first ground layer 4a and the second ground layer 4b is not limited to copper. For example, another metal material such as a copper alloy, gold, or aluminum may be used.

A material for the cover insulating layers 5a and 5b is not limited to that in the above-mentioned example. For example, another insulating material such as polyimide, polyethylene terephthalate, polyether nitrile, or polyether sulphone may be used.

Each of the through holes 6a and 6b may have an elliptical cross section, or may have a cross section in another shape such as a circular shape, a rectangular shape, or a triangular shape.

The high dielectric substance composing the high dielectric insulators 7a and 7b is not limited to barium titanate. For example, another high dielectric substance, such as another titanate such as lead titanate, zirconate such as barium zirconate, or lead zirconate titanate (PZT), may be used. The high dielectric insulators 7a and 7b may be formed of a mixture of a high dielectric substance and resin, or may be formed of only a high dielectric substance.

### (4) Correspondences Between Elements in the Claims and Parts in Embodiments

In the following paragraph, non-limiting examples of correspondences between various elements recited in the claims below and those described above with respect to various embodiments of the present invention are explained.

In the embodiments described above, the wiring pattern 2a is an example of a first conductor pattern, the area A is an example of a first area, the high dielectric insulator 7a is an example of a first high dielectric insulator, the through hole 6a is an example of a first hole, the cover insulating layer 5b is an example of a first cover insulating layer, the wiring pattern 2b is an example of a second conductor pattern, the area B is an example of a second area, the high dielectric insulator 7b is an example of a second high dielectric insulator, the through hole 6b is an example of a second hole, the cover insulating layer 5a is an example of a second cover insulating layer, and the metal plating layer 3 is an example of a connecting conductor.

As each of various elements recited in the claims, various other elements having configurations or functions described in the claims can be also used.

### INVENTIVE EXAMPLES

An inventive example and a comparative example in the present invention will be now described.

### (a) Inventive Example

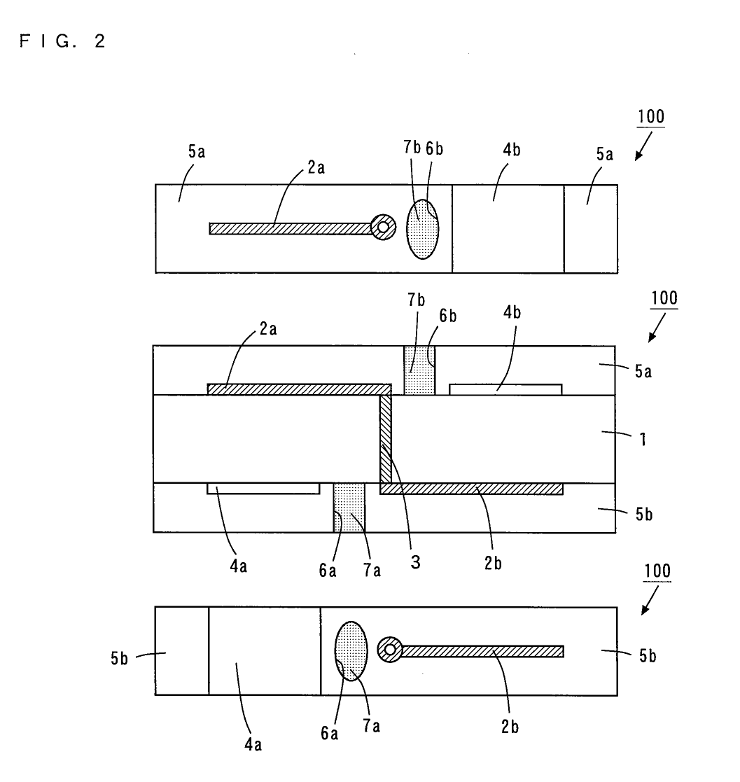

In the inventive example, a printed circuit board 100 was manufactured in accordance with the above-mentioned embodiments. FIG. 2 is a top view, a cross-sectional view, and a bottom view of the printed circuit board 100 in this inventive example. In FIG. 2, the top view, the cross-sectional view, and the bottom view of the printed circuit board 100 are respectively illustrated in an upper portion, an intermediate portion, and a lower portion.

As shown in FIG. 2, first and second ground layers 4a and 4b were formed in areas from one end to the other end in the width direction of the printed circuit board 100.

Wiring patterns 2a and 2b were formed in a line shape so as to extend toward the center in the length direction of the printed circuit board 100.

Here, the details of the printed circuit board 100 in this inventive example is as follows.

Used as a method of forming through holes 6a and 6b was a metal mold process method. The depth of each of the through holes 6a and 6b was 28 μm, and the cross-sectional shape of each of the through holes 6a and 6b was an elliptical shape (2 mm by 3 mm).

The through holes 6a and 6b were respectively filled with a high dielectric material having a dielectric constant of 10 produced by dispersing 20% by volume of barium titanate having a dielectric constant of 3300 in polyimide having a dielectric constant of 3.3, to respectively form high dielectric insulators 7a and 7b.

A characteristic impedance at a position, which is opposite to the high dielectric insulator 7a, of the wiring pattern 2a (hereinafter referred to as a first characteristic impedance) and a characteristic impedance at a position, which is opposite to the high dielectric insulator 7b, of the wiring pattern 2b (hereinafter referred to as a second characteristic impedance) were measured.

As a result, the first and second characteristic impedances respectively approximated characteristic impedances at the other positions of the wiring patterns 2a and 2b.

### (b) Comparative Example

The configuration of a printed circuit board in the comparative example differs from the configuration of the printed circuit board 100 in the inventive example in that the through holes 6a and 6b and the high dielectric insulator 7a and 7b were not provided.

In the printed circuit board of the comparative example, a characteristic impedance at a position, which is opposite to a position, which corresponds to the position of the high dielectric insulator 7a in the inventive example, of a wiring pattern 2a (hereinafter referred to as a third characteristic impedance) and a characteristic impedance at a position, which is opposite to a position, which corresponds to the position of the high dielectric insulator 7b in the inventive example, of a wiring pattern 2b (hereinafter referred to as a fourth characteristic impedance) were measured.

As a result, the third and fourth characteristic impedances were respectively higher than characteristic impedances at the other positions of the wiring patterns 2a and 2b by approximately 10Ω.

### (c) Evaluation

As can be seen from the inventive example and the comparative example, it was possible to sufficiently inhibit the characteristic impedance in the transmission path from being discontinuous by respectively forming the high dielectric insulators 7a and 7b within the cover insulating layers 5a and 5b.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A printed circuit board comprising:
a base insulating layer having a first surface and a second surface;
a first ground layer formed on said first surface of said base insulating layer;
a first conductor pattern formed on said second surface of said base insulating layer such that said first conductor pattern, which is opposite to said first ground layer excluding a part of said first conductor pattern; and
a first high dielectric insulator having a dielectric constant higher than that of said base insulating layer on a first area, which is opposite to said part of said first conductor pattern, on said first surface of said base insulating layer.

2. The printed circuit board according to claim 1, further comprising
a first cover insulating layer formed on said first surface of said base insulating layer so as to cover said first ground layer and having a first hole on said first area, wherein
said first hole is filled with said first high dielectric insulator, and the dielectric constant of said first high dielectric insulator is higher than that of said first cover insulating layer.

3. The printed circuit board according to claim 1, wherein
said first high dielectric insulator includes resin and a high dielectric substance.

4. The printed circuit board according to claim 3, wherein
said first high dielectric insulator is formed by dispersing said high dielectric substance in said resin.

5. The printed circuit board according to claim 3, wherein
said high dielectric substance includes barium titanate.

6. The printed circuit board according to claim 1, wherein
the dielectric constant of said first high dielectric insulator is not less than 10 nor more than 40.

7. The printed circuit board according to claim 1, further comprising
a second ground layer formed in an area different from said first conductor pattern on said second surface of said base insulating layer,
a second conductor pattern formed on said first surface of said base insulating layer such that the second conductor pattern is opposite to said second ground layer excluding a part of said second conductor pattern, and
a second high dielectric insulator having a dielectric constant higher than that of said base insulating layer on a second area, which is opposite to said part of said second conductor pattern, on said second surface of said base insulating layer.

8. The printed circuit board according to claim 7, further comprising
a second cover insulating layer formed on said second surface of said base insulating layer so as to cover said second ground layer and having a second hole on said second area, wherein
said second hole being filled with said second high dielectric insulator.

9. The printed circuit board according to claim 7, further comprising
a connecting conductor provided within said base insulating layer for connecting an end of said first conductor pattern and an end of said second conductor pattern, wherein
one end of said first ground layer is spaced apart from said connecting conductor, and one end of said second ground layer being spaced apart from said connecting conductor, and
said first high dielectric insulator is provided between the one end of said first ground layer and said connecting conductor, and said second high dielectric insulator is provided between the one end of said second ground layer and said connecting conductor.
